(19) United States
(12) Patent Application Publication
(10) Pub. No.: US 2006/0079097 A1
(43) Pub. Date: Apr. 13, 2006

(54) Method of forming dielectric layer in semiconductor device

(75) Inventor: Jung Geun Kim, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyungki-Do (KR)

(21) Appl. No.: 11/022,460

(22) Filed: Dec. 22, 2004

(30) Foreign Application Priority Data
Oct. 7, 2004 (KR) 2004-0079903

(51) Int. Cl. H01L 21/31

(52) U.S. Cl. 438/778

(57) ABSTRACT

A method of forming an insulating film of a semiconductor device is disclosed. Where an insulating film is formed and an annealing process is then performed to remove out-gassing sources contained in the insulating film. Spot-shaped defects and by-products or CH-radicals, which are formed on the surface of the insulating film, are then removed by thermal treatment. The generation of such defects on the surface of the insulating film is therefore minimized and potential failures such as broken or thin patterns formed on the insulating film are avoided. Accordingly, the reliability of the manufacturing process and the electrical properties of resulting devices are improved.

### BACKGROUND

1. Technical Field

A method of forming an insulating film of a semiconductor device is disclosed which minimizes defects in the insulating film.

2. Description of the Related Art

In the manufacture of semiconductor devices, insulating films are used for interlayer insulation or inter-wiring insulation. These insulating films employ TEOS (Tetraethyl Orthosilicate), BPSG (Boron Phosphorous Silicate Glass), SOD (Spin On Dielectric) and the like. Of them, a LP (low-pressure)-TEOS film has a good step coverage, good uniformity of a thickness, good productivity and so on. Thus, the LP-TEOS film has been widely used for an insulating film that does not require gap filling or spacers. However, the LP-TEOS film is unstable, the film quality can be low and it generates severe out-gassing during a subsequent thermal process.

More particularly, if a thermal process is performed after another film (for example, wiring) is deposited on the LP-TEOS film, numerous defects of a spot shape are generated because of out-gassing, as shown in FIG. 1, which is a SEM photograph showing a defect of a spot shape generated on a TEOS film. In FIG. 1, reference numeral 101 indicates the TEOS film, 102 indicates the nitride film and 103 indicates the spot shaped defect.

This spot defect causes defective pattern such as disconnection in a process of forming a pattern.

FIG. 2 is a photograph showing a defective pattern due to the existence of the spot shaped defects.

Referring to FIG. 2, if a TEOS film is formed, Ti/TiN is deposited on the TEOS film, and annealing and patterning are then performed, defects such as “convexes” and “opening” or “thinning” are created. These defects are generated over the entire wafer surface area. It was found that these defects are generated in about 317 dies and the number of defects exceeded 4000.

These defects are caused by poor film quality, which is inherent in TEOS. That is, the LP-TEOS film has a molecular structure of a Si (OC₂H₅)₄ shape and has a large amount of hydro-carbon (CₓH_{y}—) radicals. This LP-TEOS film has a property in that it is volatile while undergoing a subsequent thermal process. In reality, the LP-TEOS film has its thickness reduced by about 7.5% if annealing is performed at a temperature in the range of 800° C. in an N₂ atmosphere for about 1 hour. This 7.5% amount corresponds to a significant high value. If such out-gassing is not smoothly generated or by-product is formed, numerous defects of the spot shape will exist on the surface of the LP-TEOS film.

FIG. 3 graphically shows the different impurities existing on the surface of the TEOS film.

From FIG. 3, it can be seen that a large amount of H and C components exists on the surface of the TEOS film over the entire film thickness unlike a common insulating film, as a result of SIMS analysis.

The gas component of a high level in the TEOS film acts as an unlimited out-gassing source in a subsequent thermal process and thus causes a consistent problem. More particularly, in the case of a patterning process, spots or carbon components on the surface of the TEOS film react with a photoresist to cause a failure in which lines are broken or thinned at convex portions.

### SUMMARY OF THE DISCLOSURE

Accordingly, in view of the above problems, a method of forming an insulating film of a semiconductor device is disclosed in which the generation of defects on the surface of an insulating film is minimized and failures such as broken or thin patterns formed on the insulating film are prohibited, thereby improving the reliability of the process and the electrical properties of the resulting device. In the disclosed method, when the insulating film is formed, an annealing is performed to remove out-gassing sources contained in the insulating film, and spots, by-products or CH-radicals, which are formed on the surface of the insulating film, are removed by the thermal treatment.

One disclosed method of forming an insulating film in a semiconductor device comprises forming an interlayer insulating film on a semiconductor substrate, and performing thermal treatment so as to remove out-gassing sources contained in the interlayer insulating film.

In the above, the interlayer insulating film may be composed of any one of LP_TEOS, BPSG and SOD.

The thermal treatment can be performed in a rapid thermal processing (RTP) mode in a gas atmosphere of O₂, a gas atmosphere of N₂O or in a vacuum state. At this time, the RTP is preferably performed at a temperature ranging from 700° C. to 1000° C. for a time period ranging from 20 to 100 seconds.

Meanwhile, the thermal treatment can be performed in a furnace in a gas atmosphere of O₂, a gas atmosphere of N₂O or in a vacuum state. At this time, the thermal treatment is preferably performed at a temperature ranging from 700° C. to 1000° C. for a time period ranging from 30 minutes to 1 hour.

This method can further comprise, after the thermal treatment is performed, applying surface treatment to the interlayer insulating film in order to remove out-gassing sources or by-products adsorbed on the surface of the interlayer insulating film, or spot defects formed on the surface of the interlayer insulating film.

The surface treatment can be performed in an oxygen plasma treatment mode, a plasma etch-back mode, a wet etch-back mode or a chemical-mechanical polishing mode.

The surface treatment of the oxygen plasma treatment mode can be performed for a time period ranging from 10 to 60 seconds while applying the plasma power of 200 to 1000 W and supplying O₂ at a flow rate of 300 to 700 sccm.

The surface treatment of the plasma etch-back mode can be performed using a CₓF_{y}-based or NF-based fluorine-containing gas for a time period ranging from 10 to 50 seconds while applying a bias ranging from 300 to 500 W and at a pressure ranging from 10 mTorr to 50 mTorr. The fluorine-containing gas can employ any one of CHF₃, CF₄ and C₃F₈, or a mixture gas of at least two of them, and the flow rate of the fluorine-containing gas can be set to the range of 10 to 200 sccm.

The surface treatment of the wet etch mode can be performed using a NH₄F-based or NF-based fluorine-containing solution as an etchant at room temperature to 70° C. for a time ranging from 1 to 10 minutes. The fluorine-containing solution preferably employs a DHF solution in which H₂O and HF are mixed in the ratio of 50:1 to 200:1, or a BOE solution in which NH₄F and DHF are mixed in the ratio of 100:1 to 300:1.

In the surface treatment of a CMP mode, it is preferred that a target polishing thickness is set to below 100 Å and the slurry preferably is a silica-based slurry.

### BRIEF DESCRIPTION OF THE DRAWINGS

FIG. 1 is a photograph by an SEM, which shows a defect of a sport shape which are generated on a prior art TEOS film;

FIG. 2 is a photograph showing a prior art pattern with spot-shaped defects;

FIG. 3 is a graph showing defect measurements on the surface of a TEOS film;

FIGS. 4a to 4d are sectional views explaining a disclosed method of forming an insulating film on a semiconductor device; and

FIG. 5 is a photograph showing a reduced amount of defects on the surface of an interlayer insulating film after a disclosed thermal treatment is performed; and

FIG. 6 is a photograph showing a reduced amount of defects on the surface of an interlayer insulating film after a disclosed surface treatment is performed.

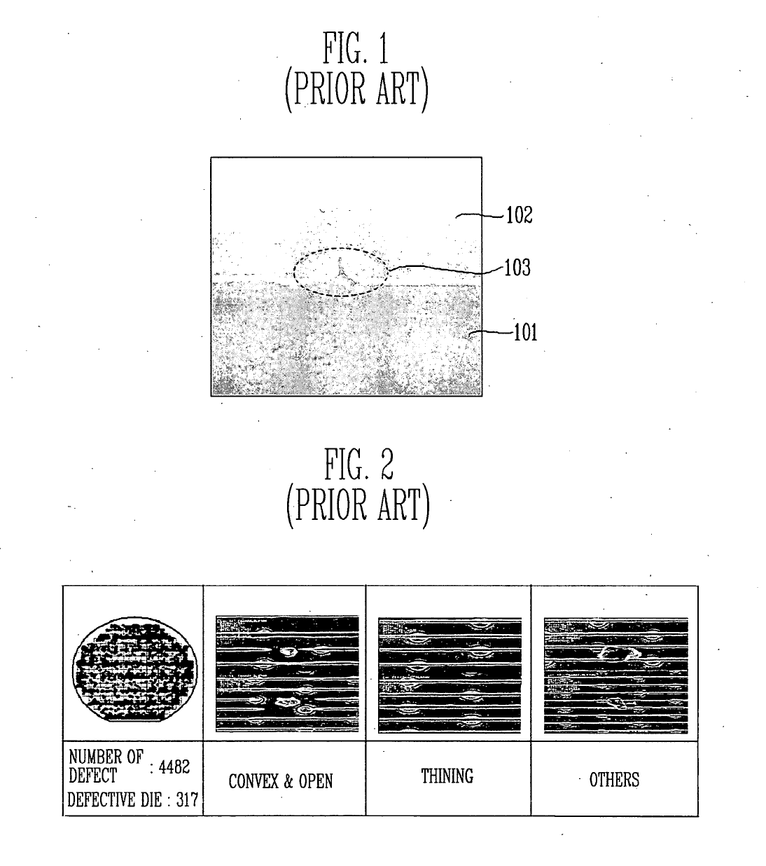

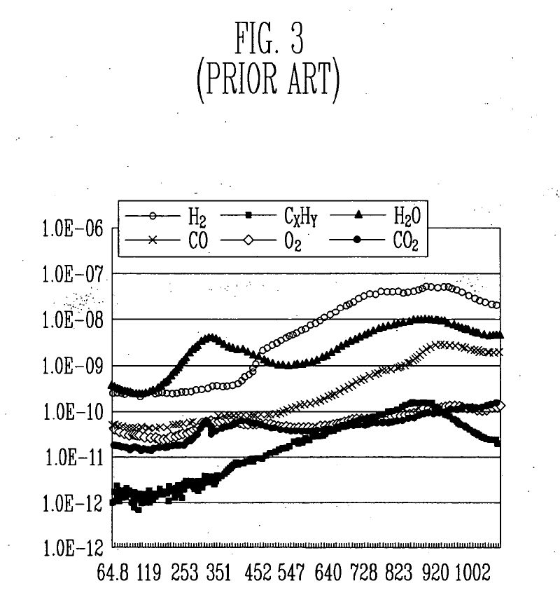

### DETAILED DESCRIPTION OF THE PRESENTLY PREFERRED EMBODIMENTS

In the drawings, the thickness and size of each layer are exaggerated for convenience and clarity. Like reference numerals are used to identify the same or similar parts. Meanwhile, in the case where one film is described as being “on” another film or a semiconductor substrate, the one film may directly or indirectly contact the other film or the semiconductor substrate. For example, a third film may be disposed between the one film and the other film or the semiconductor substrate.

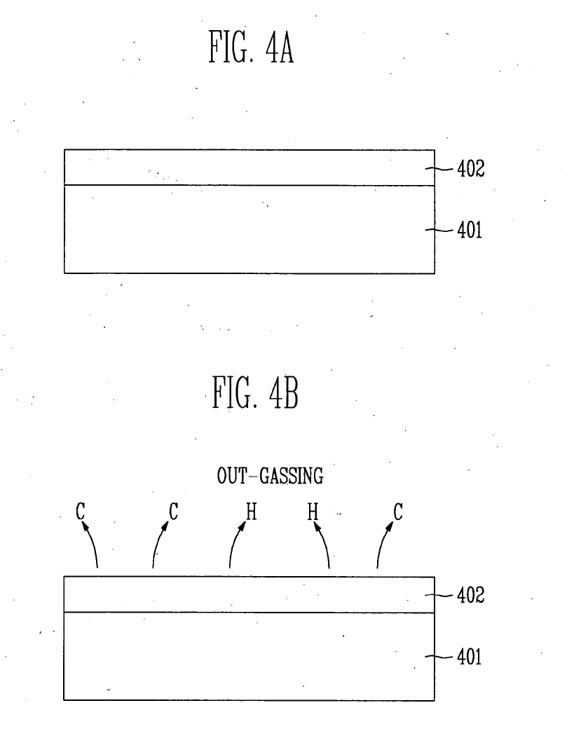

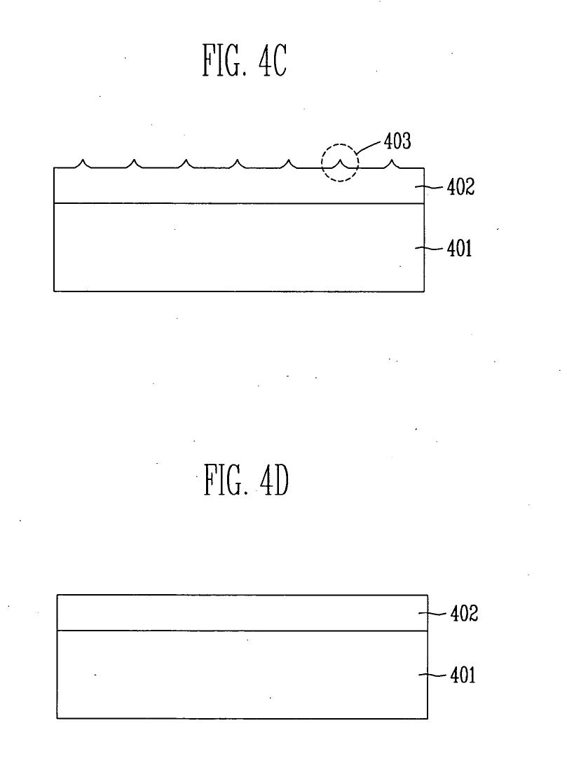

FIGS. 4a to 4d are sectional views illustrating a disclosed method for forming an insulating film on a semiconductor device. Referring to FIG. 4a, an interlayer insulating film 402 is formed on a semiconductor substrate 401 on which various elements (not shown) are formed for creating a semiconductor device, such as a transistor, a capacitor, a flash memory cell and a metal wiring.

The interlayer insulating film 402 can be formed by LP_TEOS, BPSG or SOD. A case where the interlayer insulating film 402 is formed by LP_TEOS will now be described as an example.

Referring to FIG. 4b, after the interlayer insulating film 402 is formed, annealing is performed in order to remove out-gassing sources contained in the interlayer insulating film 402.

The interlayer insulating film 402 contains a large amount of components such as carbon, hydrogen and CₓH_{y}-radical. These components all become the out-gassing sources. If out-gassing of these out-gassing sources is not performed smoothly, they can be contained in the interlayer insulating film 402, or preserved as by-products are formed on the surface of the interlayer insulating film 402. Therefore, a large quantity of spot-shaped defects may be formed.

In order to prevent this, an annealing is performed after the interlayer insulating film 402 is formed. This thermal treatment can be carried out in a rapid thermal processing (RTP) mode or in a furnace at a temperature higher than one where the interlayer insulating film 402 is deposited.

If the annealing is performed in a RTP mode, it can be performed at a temperature ranging from 700° C. to 1000° C. in a gas atmosphere of O₂ or N₂O or in a vacuum state for 20 to 100 seconds.

If the annealing is performed in the furnace, it can be performed at a temperature ranging from 700° C. to 1000° C. in a gas atmosphere of O₂ or N₂O or in a vacuum state for 30 minutes to 1 hour.

Referring to FIG. 4c, if the out-gassing sources contained in the interlayer insulating film 402 are discharged by RTP, the amount of the out-gassing sources contained in the interlayer insulating film 402 is reduced by a large amount. However, the out-gassing sources or by-products may remain or defects such as spots can be formed, on the surface of the interlayer insulating film 402.

FIG. 5 is a photograph showing defects on the surface of the interlayer insulating film after the thermal treatment is performed.

From FIG. 5, it can be seen that defects such as convexes and opening or thinning are generated although thermal treatment is performed after the interlayer insulating film 402 is formed. It can be, however, seen that a total number of defects in the wafer is 377, which is significantly reduced, and the number of dies where the defects are generated is 155, which is almost by half.

Referring to FIG. 4d, in order to remove the defects such as the out-gassing source, by-product or spots described in FIG. 4c, the interlayer insulating film 402 can experience surface treatment.

This surface treatment can be performed in an O₂ plasma treatment, plasma etch-back, wet etch-back or CMP mode.

If the surface treatment is performed in the O₂ plasma treatment mode, it can be performed for a time period of 10 to 60 seconds while applying the plasma power ranging from 200 to 1000 W and supplying O₂ at a flow rate ranging from 300 to 700 sccm.

If the surface treatment is performed in the plasma etch-back mode, it can be performed using a CₓF_{y}-based or NF-based fluorine-containing gas for a time period of 10 to 50 seconds while applying a bias ranging from 300 to 500 W at a pressure ranging from 10 mTorr to 50 mTorr. The fluorine-containing gas may employ one of CHF₃, CF₄ and C₃F₈, or a mixture of at least two of them, and the flow rate can range from 10 to 200 sccm.

If the surface treatment is performed in the wet etch mode, it can be performed using a NH₄F-based or NF-based fluorine-containing solution as an etchant at a range from room temperature to 70° C. for a time period ranging from 1 to 10 minutes. In this time, the fluorine-containing solution can employ a DHF solution in which H₂O and HF are mixed in the ratio of 50:1 to 200:1, or a BOE solution in which NH₄F and DHF are mixed in the ratio of 100:1 to 300:1.

If the surface treatment is performed in the CMP mode, it is preferred that a target polishing thickness be set to below 100 Å because this treatment is performed for the purpose of surface treatment or defect removal, not polishing. The slurry preferably includes a silica-based (SiO₂) slurry if a film to be polished is a TEOS-based oxide film.

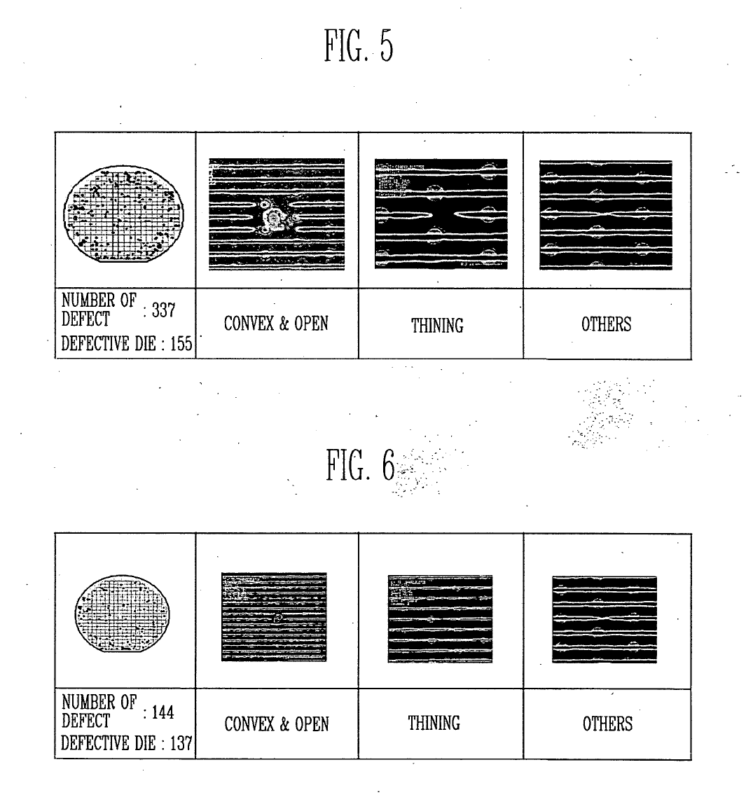

FIG. 6 is a photograph showing defects on the surface of an interlayer insulating film after a surface treatment is performed. From FIG. 6, it can be seen that defects such as convexes and opening or thinning are generated although thermal treatment is performed after the interlayer insulating film 402 is formed. It can be, however, seen that a total number of defects in the wafer is 144, which is dramatically reduced, and the number of dies where the defects are generated is 137, which, again, is dramatically reduced. The data of FIG. 6 shows a clear and dramatic, surprising and unexpected improvement over that shown in FIG. 3.

As described above, an insulating film is formed and an annealing process is then performed to remove out-gassing sources contained in the insulating film. Spots, by-products or CH-radicals, which are formed on the surface of the insulating film, are then removed by thermal treatment. Therefore, generation of defects on the surface of the insulating film is minimized and a fail such as broken or thin patterns formed on the insulating film is prohibited. Accordingly, the disclosed is advantageous in that it can improve reliability of a process and electrical properties of devices.

Although the foregoing description has been made with reference to the preferred embodiments, it is to be understood that changes and modifications to the disclosed methods may be made by the ordinary skilled in the art without departing from the spirit and scope of the appended claims.

What is claimed is:

1. A method of forming an insulating film in a semiconductor device, comprising:
forming an interlayer insulating film on a semiconductor substrate; and
performing thermal treatment to remove out-gassing sources contained in the interlayer insulating film.

2. The method as claimed in claim 1, wherein the interlayer insulating film is composed of any one of LP_TEOS, BPSG and SOD.

3. The method as claimed in claim 1, wherein the thermal treatment is performed in a rapid thermal processing (RTP) mode in a gas atmosphere of O₂, a gas atmosphere of N₂O or in a vacuum state.

4. The method as claimed in claim 3, wherein the RTP is performed at a temperature ranging from 700° C. to 1000° C. for 20 to 100 seconds.

5. The method as claimed in claim 3, wherein the thermal treatment is performed in a furnace in a gas atmosphere of O₂, a gas atmosphere of N₂O or in a vacuum state.

6. The method as claimed in claim 5, wherein the thermal treatment is performed at a temperature ranging from 700° C. to 1000° C. for 30 minutes to 1 hour.

7. The method as claimed in claim 1, further comprising, after the thermal treatment is performed, applying a surface treatment to the interlayer insulating film in order to further remove out-gassing sources or by-products adsorbed on the surface of the interlayer insulating film, or spot defects formed on the surface of the interlayer insulating film.

8. The method as claimed in claim 7, wherein the surface treatment is performed in an oxygen plasma treatment mode, a plasma etch-back mode, a wet etch-back mode or a chemical-mechanical polishing mode.

9. The method as claimed in claim 8, wherein the surface treatment of the oxygen plasma treatment mode is performed for 10 to 60 seconds while applying the plasma power of 200 to 1000 W and supplying O₂ of 300 to 700 sccm.

10. The method as claimed in claim 8, wherein the surface treatment of the plasma etch-back mode is performed using a CₓF_{y}-based or NF-based fluorine-containing gas for 10 to 50 seconds while applying a bias of 300 to 500 W at a pressure of 10 mTorr to 50 mTorr.

11. The method as claimed in claim 10, wherein the fluorine-containing gas employs one of CHF₃, CF₄ and C₃F₈, or a mixture of any two thereof.

12. The method as claimed in claim 11, wherein the flow rate of the fluorine-containing gas is set to 10 to 200 sccm.

13. The method as claimed in claim 7, wherein the surface treatment of the wet etch mode is performed using an NH₄F-based or NF-based fluorine-containing solution as an etchant at a temperature ranging from room temperature to 70° C. for 1 to 10 minutes.

14. The method as claimed in claim 13, wherein the fluorine-containing solution employs a DHF solution in which H₂O and HF are mixed in the ratio of 50:1 to 200:1, or a BOE solution in which NH₄F and DHF are mixed in the ratio of 100:1 to 300:1.

15. The method as claimed in claim 7, wherein in the surface treatment of a CMP mode, a target polishing thickness is set to below 100 Å and the CMP mode uses a CMP slurry that is a silica-based slurry.
